(19) United States
(12) Patent Application Publication
(10) Pub. No.: US 2025/0054838 A1
(43) Pub. Date: Feb. 13, 2025

(54) THREE-DIMENSIONAL INTEGRATED CIRCUIT AND MANUFACTURING METHOD THEREFOR

(71) Applicant: INSTITUTE OF MICROELECTRONICS, CHINESE ACADEMY OF SCIENCES, Beijing (CN)

(72) Inventors: Guanhua YANG, Beijing (CN); Wendong LU, Beijing (CN); Ling LI, Beijing (CN)

(73) Assignee: INSTITUTE OF MICROELECTRONICS, CHINESE ACADEMY OF SCIENCES, Beijing (CN)

(21) Appl. No.: 18/697,389

(22) PCT Filed: Mar. 6, 2023
(86) PCT No.: PCT/CN2023/079911

§ 371 Date: Mar. 29, 2024

(30) Foreign Application Priority Data
May 11, 2022 (CN) 202210515402.X

(51) Int. Cl. H01L 23/48; H01L 27/06; H01L 29/417

(52) U.S. Cl. CPC H01L 23/481; H01L 27/0688; H01L 29/41725

(57) ABSTRACT

A three-dimensional integrated circuit and a manufacturing method therefor is used for improving the performance of the integrated circuit when the integrated circuit includes a power gating circuit. The three-dimensional integrated circuit includes a substrate, and a front-section circuit, a rear-section metal interconnection layer, and a rear-section power gating circuit that are formed on the substrate; the rear-section metal interconnection layer is formed on the front-section circuit; the rear-section power gating circuit is located in the rear-section metal interconnection layer; and the front-section circuit is electrically connected to a power supply or a ground wire by means of the rear-section metal interconnection layer and the rear-section power gating circuit.

### CROSS REFERENCE TO RELATED APPLICATION

The present application claims the priority to Chinese Patent Application No. 202210515402.X, titled “THREE-DIMENSIONAL INTEGRATED CIRCUIT AND MANUFACTURING METHOD THEREFOR”, filed with the China National Intellectual Property Administration (CNIPA) on May 11, 2022, which is incorporated herein by reference in its entirety.

### TECHNICAL FIELD

The present disclosure relates to the technical field of semiconductors, and in particular, to a three-dimensional (3D) integrated circuit and a manufacturing method thereof.

### BACKGROUND

Power gating is a technique used to reduce power consumption by using a switch transistor to break the connection between an internal circuit and a power supply or the connection between an internal circuit and a ground wire when a circuit is in a standby mode to turn off the power supply to the internal circuit.

However, existing integrated circuits using power gating have poor performance.

### SUMMARY

An objective of the present disclosure is to provide a 3D integrated circuit and a manufacturing method thereof, for improving performance of an integrated circuit having a power gating circuit.

To achieve the foregoing objective, the present disclosure provides a 3D integrated circuit, including: a substrate, a front-end circuit formed on the substrate, a back-end metal interconnect layer, and a back-end power gating circuit. The back-end metal interconnect layer is formed on the front-end circuit. The back-end power gating circuit is located in the back-end metal interconnect layer. The front-end circuit is electrically connected to a power supply or a ground wire through the back-end metal interconnect layer and the back-end power gating circuit.

Compared with the prior art, in the 3D integrated circuit provided in the present disclosure, the back-end metal interconnect layer is located on the front-end circuit. In addition, the back-end power gating circuit is located in the back-end metal interconnect layer. In other words, the back-end power gating circuit and the front-end circuit are vertically distributed in different layers, thereby achieving the monolithic 3D integration of the power gating circuit and the circuit. Based on this, compared with the existing integrated circuit in which the contained front-end circuit and the power gating circuit are horizontally distributed in the same layer, in the 3D integrated circuit provided in the present disclosure, although the power gating circuit is introduced, no additional area overheads of the 3D integrated circuit are increased. That is, the integration intensity of the 3D integrated circuit can be increased while static power consumption of the 3D integrated circuit is reduced. In addition, the back-end power gating circuit is located on the front-end circuit, so that current transmission paths between the power supply (or the ground wire), the back-end power gating circuit, and the front-end circuit extend along a single direction, thereby helping resolve the problems in the existing integrated circuit of an extremely long transmission path and complex circuit layout and wiring resulting from the horizontal distribution of the front-end circuit and the power gating circuit in the same layer that causes the current transmission path to extend from top to bottom and then from bottom to top to complete the corresponding signal transmission. In addition, the front-end circuit, the back-end metal interconnect layer, and the back-end power gating circuit are formed on the same substrate, such that a distance between the front-end circuit and the back-end power gating circuit is reduced, thus further shortening and simplifying a power supply transmission path, thereby further helping reduce a voltage drop of the 3D integrated circuit and improve the performance of the 3D integrated circuit.

The present disclosure further provides a manufacturing method of a 3D integrated circuit, including:
providing a substrate;
forming a front-end circuit on the substrate; and
forming, on the front-end circuit, a back-end metal interconnect layer and a back-end power gating circuit located in the back-end metal interconnect layer. The front-end circuit is electrically connected to a power supply or a ground wire through the back-end metal interconnect layer and the back-end power gating circuit.

The beneficial effects of the manufacturing method of a 3D integrated circuit provided in the present disclosure are the same as the beneficial effects of the 3D integrated circuit provided in the present disclosure. Details are not described herein again.

### BRIEF DESCRIPTION OF THE DRAWINGS

The accompanying drawings described herein are provided for further understanding of the present disclosure, and constitute a part of the present disclosure. The exemplary embodiments and illustrations of the present disclosure are intended to explain the present disclosure, but do not constitute inappropriate limitations to the present disclosure. In the accompanying drawings:

FIG. 1 is a block diagram of an integrated circuit principle of manufacturing a power gating circuit by using a front-end-of-line (FEOL) process in the prior art;

FIG. 2 is a diagram of an integrated circuit principle of manufacturing a power gating circuit by using an FEOL process in the prior art;

FIG. 3 is a block principle diagram of a 3D integrated circuit according to an embodiment of the present disclosure;

FIG. 4 is a principle diagram of a 3D integrated circuit according to an embodiment of the present disclosure;

FIG. 5 is a schematic exploded structural diagram of a 3D integrated circuit according to an embodiment of the present disclosure; and

FIG. 6 is a flowchart of a manufacturing method of a 3D integrated circuit according to an embodiment of the present disclosure.

Reference numerals: 11—substrate, 12—front-end circuit, 121—logic/analog transistor, 13—interlayer isolation layer, 14—back-end metal interconnect layer, 15—back-end power gating circuit, 151—power gating transistor, 1511—gate, 1512—gate dielectric layer, 15121—first dielectric layer, 15122—second dielectric layer, 1513—channel, 1514—source region, 1515—drain region, 1516—source, and 1517—drain.

### DETAILED DESCRIPTION OF THE EMBODIMENTS

The embodiments of the present disclosure are described below with reference to the accompanying drawings. However, it should be understood that these descriptions are merely exemplary and are not intended to limit the scope of the present disclosure. In addition, in the following description, descriptions of conventional structures and technologies are omitted to avoid unnecessarily confusing the concepts of the present disclosure.

Various schematic structural diagrams of the embodiments of the present disclosure are illustrated in the accompanying drawings. These drawings are not drawn to scale, in which some details are enlarged to be seen clearly, and some details may be omitted. The shapes of various regions and layers shown in the drawings and relative sizes and positional relationships thereof are merely exemplary, which may be different due to manufacturing tolerances or technical limitations in practice, and those skilled in the art may additionally design regions/layers with different shapes, sizes and relative positions according to actual needs.

In the context of the present disclosure, when a layer/element is referred to as being “on” another layer/element, it may be directly on the another layer/element, or there may be an intermediate layer/element present therebetween. In addition, if a layer/element is “on” another layer/element in one orientation, the layer/element may be “under” the another layer/element when the orientation is reversed. To make the to-be-resolved technical problems, the technical solutions, and the beneficial effects of the present disclosure clearer, the present disclosure is described in further detail below with reference to the accompanying drawings and embodiments. It should be understood that the specific embodiments described herein are only intended to explain the present disclosure and are not intended to limit the present disclosure.

In addition, the terms “first” and “second” are merely intended for a purpose of description, and shall not be understood as an indication or implication of relative importance or implicit indication of a quantity of indicated technical features. Thus, features defined with “first” and “second” may explicitly or implicitly include one or more of the features. In the description of the present disclosure, “a plurality of” means two or more, unless otherwise specifically defined. “Multiple” means one or more, unless otherwise specifically defined.

In the description of the present disclosure, it should be noted that unless otherwise expressly specified and defined, terms such as “mounted”, “connected to”, and “connected with” should be comprehended in a broad sense. For example, the “connection” may be a fixed connection, a removable connection, or an integral connection; may be a mechanical connection, an electrical connection, or mutual communication; may be a direct connection or an indirect connection via an intermediate medium; or may be an interconnection or an interaction relationship between two elements. Those of ordinary skill in the art may understand specific meanings of the above terms in the present disclosure based on a specific situation.

With the advancement of semiconductor process technologies, electronic devices (such as notebook computers and mobile phones) can perform increasingly complex functions. However, energy storage capabilities of energy storage elements (such as batteries) of the electronic devices are not increased at the same rate. As a result, the power consumption problem has become a major constraint in the design of integrated circuits. Specifically, considering the composition of total circuit power consumption, there may be two methods for reducing circuit power consumption: dynamic low-power consumption method and static low-power consumption method. In addition, as the silicon-based complementary metal oxide semiconductor (CMOS) technology continues to shrink to technology nodes below 5 nm, the power dissipation problem caused by static power consumption has become increasingly prominent, and has even become a determining factor in total power consumption of chips.

Regarding how to reduce the static power consumption, those skilled in the art have studied many methods. For example, from a process level perspective, a gate dielectric layer with a high dielectric constant value can be used to reduce a leakage current of a device, thereby reducing leakage power consumption of the circuit. In addition, in terms of the current mainstream process, a subthreshold leakage of the device is a main factor of an electric leakage. Therefore, for how to reduce static power consumption, how to reduce the subthreshold leakage current of the device is first considered. Moreover, because a method for reducing circuit power consumption at a circuit level is the most achievable, reducing the subthreshold leakage is mostly considered at the circuit level. The most effective method is to use power gating. The power gating is a technique used to reduce power consumption by using a switch transistor to break the connection between an internal circuit and a power supply or the connection between an internal circuit and a ground wire when a circuit is in a standby mode to turn off the power supply to the internal circuit.

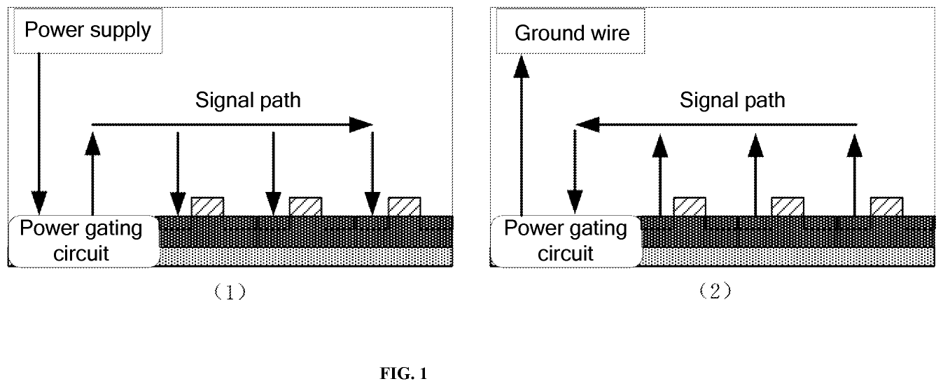

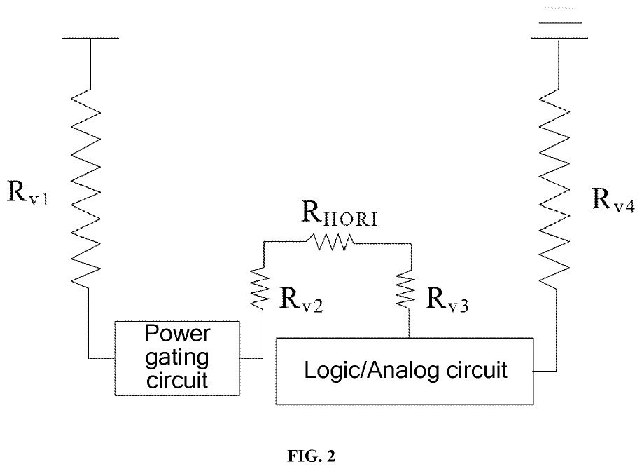

However, as shown in FIG. 1 and FIG. 2, a power gating circuit in a current mainstream silicon-based integrated circuit is manufactured by using an FEOL process. This faces the integrated circuit with at least the following technical problem: As shown in (1) and (2) in FIG. 1 and FIG. 2, a current transmission path from a power supply (or a ground wire) to the integrated circuit is relatively long. Correspondingly, as an example, a front-end logic/analog circuit is connected to the power supply through a power gating circuit and a metal interconnect layer. In FIG. 2, for a transmission line resistance Rᵥ₁ between the power supply and the power gating circuit, transmission line resistances Rᵥ₂, R_{HORI}, and Rᵥ₃ between the power gating circuit and the logic/analog circuit, and a transmission line resistance Rᵥ₄ between the logic/analog circuit and the ground wire, a total resistance of the foregoing three types of transmission line resistances increases as the current transmission path increases. As a result, an additional IR drop (voltage loss) is introduced, leading to performance degradation of the integrated circuit. As shown in FIG. 1 and FIG. 2, the power gating circuit manufactured by using the FEOL process and the front-end logic/analog circuit are horizontally arranged, the introduction of the power gating circuit occupies a large chip area, which is not conducive to miniaturization of the integrated circuit. The introduction of the power gating circuit further makes the layout and routing of the integrated circuit more complex.

To resolve the foregoing technical problem, the embodiments of the present disclosure provide a 3D integrated circuit and a manufacturing method thereof. In the 3D integrated circuit provided in the embodiments of the present disclosure, a back-end metal interconnect layer is formed on a front-end circuit. In addition, a back-end power gating circuit is located in the back-end metal interconnect layer, to reduce static power consumption of the 3D integrated circuit, thereby helping increase integration intensity of the 3D integrated circuit. In addition, the front-end circuit, the back-end metal interconnect layer, and the back-end power gating circuit are formed on a same substrate, such that a distance between the front-end circuit and the back-end power gating circuit is reduced, thus further shortening a power supply transmission path, thereby further helping reduce a voltage drop of the 3D integrated circuit and improve the performance of the 3D integrated circuit.

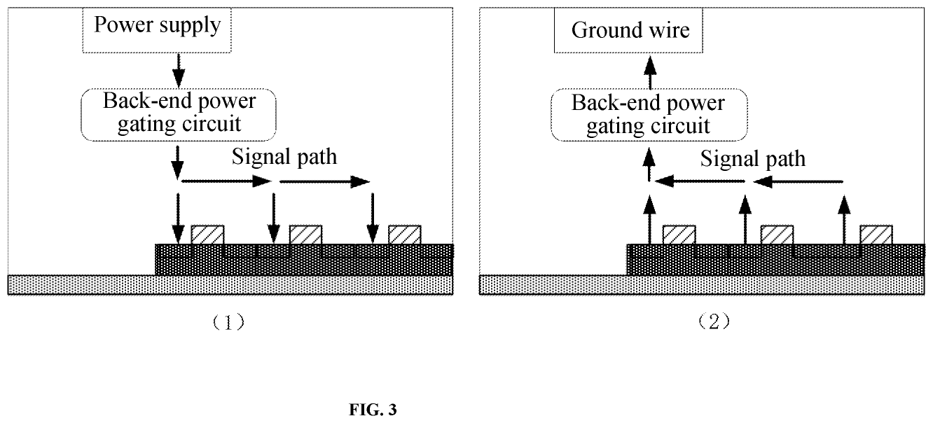

An embodiment of the present disclosure provides a 3D integrated circuit. As shown in FIG. 3 to FIG. 5, the 3D integrated circuit includes a substrate 11, a front-end circuit 12 formed on the substrate 11, a back-end metal interconnect layer 14, and a back-end power gating circuit 15. The back-end metal interconnect layer 14 is formed on the front-end circuit 12. The back-end power gating circuit 15 is located in the back-end metal interconnect layer 14. The front-end circuit 12 is electrically connected to a power supply or a ground wire through the back-end metal interconnect layer 14 and the back-end power gating circuit 15.

Specifically, the substrate may be any substrate, such as a silicon oxide wafer substrate, as long as the substrate can be applied to the 3D integrated circuit provided in the embodiments of the present disclosure. In addition, the front-end circuit may be a front-end logic circuit or a front-end analog circuit. It can be understood that, according to different application scenarios of the 3D integrated circuit, specific structures, materials, specifications, and other information of the front-end circuit, the back-end metal interconnect layer, and the back-end power gating circuit may not be completely the same or may be different. Therefore, the specific structures and other information of the front-end circuit, the back-end metal interconnect layer, and the back-end power gating circuit may be set according to actual application scenarios. This is not specifically limited herein. In addition, as shown in (1) and (2) in FIG. 3, whether the front-end circuit is electrically connected to the power supply or to the ground wire through the back-end metal interconnect layer and the back-end power gating circuit may be specifically set according to actual requirements and specific structures of the power gating circuit. For example, when the power gating circuit includes at least one power gating transistor, and the power gating transistor is a P-channel metal oxide semiconductor (PMOS) transistor, the front-end circuit may be electrically connected to the power supply through the back-end metal interconnect layer and the back-end power gating circuit. The front-end circuit is connected to a drain of the power gating transistor. The power supply is connected to a source of the power gating transistor. For another example, when the power gating circuit includes at least one power gating transistor, and the power gating transistor is an N-channel MOS transistor, the front-end circuit may be electrically connected to the ground wire through the back-end metal interconnect layer and the back-end power gating circuit. The front-end circuit is connected to a drain of the power gating transistor. The ground wire is connected to a source of the power gating transistor.

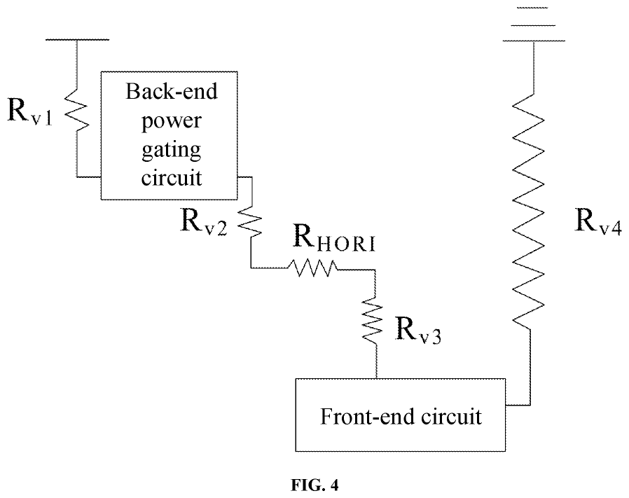

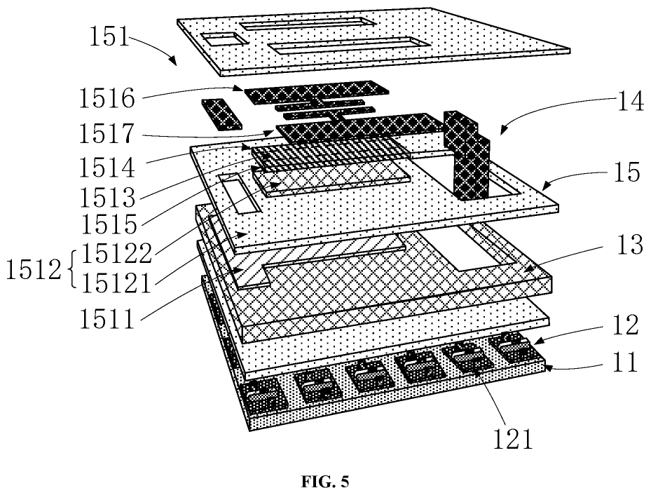

Furthermore, a position of the back-end power gating circuit in the back-end metal interconnect layer affects a relative positional relationship between the back-end power gating circuit and the front-end circuit, and further affects distribution and lengths of current transmission paths between the power supply (or the ground wire), the back-end power gating circuit, and the front-end circuit. Therefore, relative positions of the back-end power gating circuit and the front-end circuit may be designed according to requirements on current transmission paths. For example, as shown in FIG. 4, along a thickness direction of the substrate, the back-end power gating circuit may be located obliquely above the front-end circuit, and the two circuits partially overlap at positions in a vertical direction. In FIG. 4, Rᵥ₁ is a transmission line resistance between the power supply and the back-end power gating circuit. Rᵥ₂, R_{HORI}, and Rᵥ₃ are transmission line resistances between the back-end power gating circuit and the front-end circuit. Rᵥ₄ is a transmission line resistance between the front-end circuit and the ground wire. For another example, as shown in FIG. 3 and FIG. 5, the front-end circuit 12 and the back-end power gating circuit 15 are vertically stacked along a thickness direction of the substrate 11. In this case, the back-end power gating circuit 15 is located directly above the front-end circuit 12. This helps the current transmission path to extend along a single direction perpendicular to a surface of the substrate 11, thereby shortening the current transmission path and reducing a voltage loss of the 3D integrated circuit to the greatest extent. In addition, circuit cabling can be simplified and the design and manufacturing of the 3D integrated circuit can be easier.

In some cases, as shown in FIG. 5, the 3D integrated circuit may further include an interlayer isolation layer 13 located between the front-end circuit 12 and the back-end metal interconnect layer 14 to effectively prevent an electric field produced by the back-end metal interconnect layer 14 and the back-end power gating circuit 15 from affecting the front-end circuit 12 when the 3D integrated circuit is in a working state, thereby ensuring that a non-contact region between the front-end circuit 12 and the back-end metal interconnect layer 14 is electrically insulated to suppress the electric leakage. Specifically, the interlayer isolation layer 13 may be made of silicon dioxide or other insulating materials. A thickness of the interlayer isolation layer 13 may be set according to actual requirements. For example, the thickness of the interlayer isolation layer 13 may range from 100 nm to 400 nm.

It can be learned from the foregoing content that, in the 3D integrated circuit provided in this embodiment of the present disclosure, the back-end metal interconnect layer is located on the front-end circuit. In addition, the back-end power gating circuit is located in the back-end metal interconnect layer. In other words, the back-end power gating circuit and the front-end circuit are vertically distributed in different layers. Based on this, as shown in FIG. 3 to FIG. 5, compared with the existing integrated circuit in which the included front-end circuit and the power gating circuit are horizontally distributed in the same layer, in the 3D integrated circuit provided in this embodiment of the present disclosure, although the power gating circuit is introduced, no additional area overheads of the 3D integrated circuit are increased. That is, integration intensity of the 3D integrated circuit can be increased while static power consumption of the 3D integrated circuit is reduced. In addition, the back-end power gating circuit 15 is located on the front-end circuit 12, so that current transmission paths between the power supply (or the ground wire), the back-end power gating circuit 15, and the front-end circuit 12 extend along a single direction, thereby helping resolve the problems in the existing integrated circuit of an extremely long current transmission path and complex circuit layout and wiring resulting from the horizontal distribution of the front-end logic/analog circuit and the power gating circuit in the same layer that causes the current transmission path to extend from top to bottom and then from bottom to top to complete the corresponding signal transmission. In addition, the front-end circuit 12, the back-end metal interconnect layer 14, and the back-end power gating circuit 15 are formed on the same substrate 11, such that a distance between the front-end circuit 12 and the back-end power gating circuit 15 is reduced, thus further shortening and simplifying a power supply transmission path, thereby further helping reduce a voltage drop of the 3D integrated circuit and improve the performance of the 3D integrated circuit.

In an example, as shown in FIG. 5, the back-end power gating circuit 15 includes at least one power gating transistor 151. The at least one power gating transistor 151 includes a channel 1513 made of amorphous indium gallium zinc oxide. It should be understood that, because the amorphous indium gallium zinc oxide material has a relatively large on/off (ION/IOFF) ratio, a low temperature process, a relatively low subthreshold swing (SS), relatively high mobility, and other features, when the channel 1513 of the power gating transistor 151 of the back-end power gating circuit 15 is amorphous indium gallium zinc oxide, the power gating transistor 151 has a relatively low off-state current, thereby helping alleviate the electric leakage. This also helps manufacture the back-end power gating circuit 15 on the front-end circuit 12 by using a low temperature process, to prevent the front-end circuit 12 from being affected by a high temperature process during the formation of the power gating transistor 151 to degrade the working performance of the front-end circuit 12.

Specifically, a structure type of the power gating transistor may be set according to actual requirements. For example, the power gating transistor may be a planar transistor, a fin field-effect transistor, a gate-all-around transistor, or the like.

As shown in FIG. 5, when the back-end power gating circuit 15 includes at least one power gating transistor 151, the power gating transistor 151 may include a source region 1514, a drain region 1515, a channel 1513, a gate stack, a source 1516, and a drain 1517. Specifically, the channel 1513 is located between the source region 1514 and the drain region 1515. The source 1516 is electrically connected to the source region 1514. The drain 1517 is electrically connected to the drain region 1515. A relative positional relationship between the gate stack and the channel 1513 varies with different structure types of the power gating transistor 151. For example, when the power gating transistor 151 is a planar transistor, the gate stack is formed on a surface of the channel 1513 facing away from the substrate 11. For another example, when the power gating transistor is a gate-all-around transistor, the gate stack surrounds a periphery of the channel. The gate stack includes a gate dielectric layer 1512 and a gate 1511 formed on the gate dielectric layer 1512.

The source region and the drain region of the power gating transistor may also be made of amorphous indium gallium zinc oxide or other semiconductor materials. Each of a source, a drain, and a gate of the power gating transistor may be made of a conductive material such as titanium and/or gold. It should be understood that, in an actual application process, the titanium and gold materials can be patterned through a non-dry etching manner such as a lift-off process. In addition, during the manufacturing of an upper-layer device, if a dry etching process is used to pattern a source, a drain, a gate, and other metallic materials of the upper-layer device, problems such as uneven top interfaces may occur due to excessive etching. This further affects a yield of the upper-layer device and makes it difficult to pattern subsequent structures on the uneven interfaces, thus affecting the formation of subsequent structures. Based on this, when the source, the drain, and the gate of the power gating transistor are made of titanium and/or gold, they can be formed through a non-dry etching manner such as a lift-off process. This helps planarize a top interface of the power gating transistor, and facilitates the formation of a portion of another structure located on the power gating transistor such as the back-end metal interconnect layer, thereby improving the yield of the 3D integrated circuit. Certainly, the source, the drain, and the gate of the power gating transistor may alternatively be made of other conductive materials that can be patterned through a non-dry etching manner such as a lift-off process.

In addition, the gate dielectric layer of the power gating transistor may be a single-layer structure, or a laminated structure including at least two dielectric layers. For example, when the gate dielectric layer of the power gating transistor is a single-layer structure, the gate dielectric layer of the power gating transistor may be made of an insulating material with a relatively low dielectric constant such as silicon oxide or silicon nitride, or may be an insulating material with a relatively high dielectric constant such as HfO₂, ZrO₂, TiO₂, or Al₂O₃. For another example, as shown in FIG. 5, when the gate dielectric layer 1512 of the power gating transistor 151 is a laminated structure, the gate dielectric layer 1512 of the power gating transistor 151 may include a first dielectric layer 15121 and a second dielectric layer 15122 located on the first dielectric layer 15121. The first dielectric layer 15121 may be made of aluminum oxide. The second dielectric layer 15122 may be made of silicon dioxide. In this case, the gate dielectric layer of the power gating transistor 151 is formed by stacking a second aluminum oxide layer and a second silicon dioxide layer. The second silicon dioxide layer is located between the second aluminum oxide layer and the channel 1513 of the power gating transistor 151. It should be understood that, when the material of the gate dielectric layer 1512 of the power gating transistor 151 includes a dielectric material with a high dielectric constant and the material of the gate 1511 of the power gating transistor 151 includes a metallic material, it helps resolve an electric leakage problem of the gate dielectric layer 1512 of the power gating transistor 151 after the power gating transistor 151 is miniaturized. In addition, when the channel 1513 of the power gating transistor 151 is made of amorphous indium gallium zinc oxide, the second aluminum oxide layer with a smaller thickness may be formed by using an atomic layer deposition process and both the second silicon dioxide layer and the channel 1513 of the power gating transistor 151 may be formed by using a magnetron sputtering process. Based on this, in an actual application process, after the second aluminum oxide layer is formed in a device that can support the atomic layer deposition process and the formed structure is transferred to a device that can support the magnetron sputtering process, an interface of the second aluminum oxide layer close to the channel 1513 is less clean. In this case, the magnetron sputtering process may be used to first form a second silicon dioxide layer on the second aluminum oxide layer, such that an interface forming the channel 1513 of the power gating transistor 151 is cleaner, thereby helping improve performance consistency of the power gating transistor 151.

In an example, as shown in FIG. 5, the front-end circuit 12 includes at least one logic/analog transistor 121. Specifically, for a specific structure of the logic/analog transistor 121, reference may be made to the structure of the power gating transistor 151 described above. Details are not described herein again.

A source and a drain of the at least one logic/analog transistor may be made of a conductive material such as titanium and/or gold. A gate of the logic/analog transistor may be made of a conductive material such as molybdenum. A source region, a drain region, and a channel of the logic/analog transistor may be made of a semiconductor material such as silicon, germanium silicon, germanium, or amorphous indium gallium zinc oxide. A gate dielectric layer of the logic/analog transistor may be made of a single-layer structure or a laminated structure. Specifically, when the gate dielectric layer of the logic/analog transistor is a single-layer structure, for a material of the gate dielectric layer, reference may be made to the material of the gate dielectric layer of the power gating transistor. When the gate dielectric layer of the logic/analog transistor is a laminated structure, the gate dielectric layer of the logic/analog transistor may be formed by stacking a first aluminum oxide layer and a first silicon dioxide layer. The first silicon dioxide layer is located between the channel of the logic/analog transistor and the first aluminum oxide layer. For beneficial effects in this case, reference may be made to the beneficial effects achieved when the gate dielectric layer of the power gating transistor is formed by stacking a second aluminum oxide layer and a second silicon dioxide layer. Details are not described herein again.

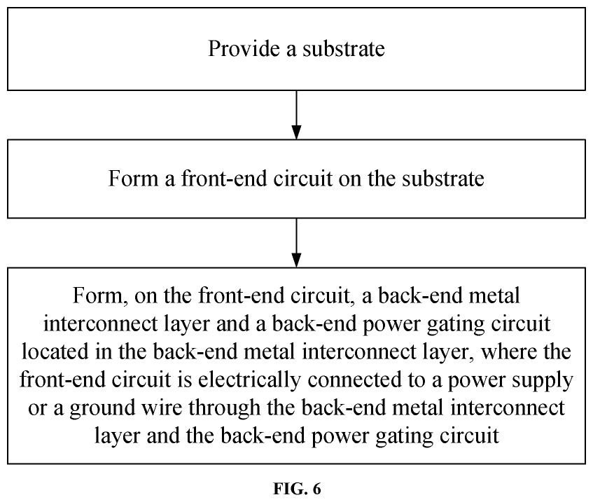

As shown in FIG. 6, an embodiment of the present disclosure provides a manufacturing method of a 3D integrated circuit. Specifically, the manufacturing method of a 3D integrated circuit includes: providing a substrate. Subsequently, a front-end circuit is formed on the substrate. As shown in FIG. 3 to FIG. 5, finally, a back-end metal interconnect layer 14 and a back-end power gating circuit 15 located in the back-end metal interconnect layer 14 are formed on the front-end circuit 12. The front-end circuit 12 is electrically connected to a power supply or a ground wire through the back-end metal interconnect layer 14 and the back-end power gating circuit 15.

Specifically, for a material of the substrate, and specific structures, materials, specifications, and other information of the front-end circuit, the back-end metal interconnect layer, and the back-end power gating circuit, reference may be made to the foregoing descriptions.

In an actual application process, the front-end circuit is formed on the substrate by using an FEOL process. For example, a gate material may be sputtered on a silicon/silicon oxide substrate by using a magnetron sputtering process. In addition, the gate material is patterned by using a dry etching process to obtain a gate of a logic/analog transistor of the front-end circuit. Subsequently, a first dielectric material layer may be formed on the substrate and the gate of the logic/analog transistor by using an atomic layer deposition process, and the first dielectric material layer is patterned, to retain only a part of the first dielectric material layer located on the gate of the logic/analog transistor to obtain a first dielectric layer (a material of the first dielectric layer may be aluminum oxide or the like). Then, a second dielectric material layer and a semiconductor material layer are sequentially coated on the formed structure by using the magnetron sputtering process, and the foregoing two films are patterned, such that the remaining part of the second dielectric material layer forms a second dielectric layer (a material of the second dielectric layer may be silicon dioxide or the like), and the remaining part of the semiconductor material layer forms a source region, a drain region, and a channel of the logic/analog transistor. The first dielectric layer and the second dielectric layer constitute a gate dielectric layer of the logic/analog transistor. Finally, a mask layer for exposing the source region and the drain region of the logic/analog transistor is manufactured on the formed structure by patterning or other processes. Then, coated with the mask layer, a source and a drain respectively in contact with the source region and the drain region are formed by using sputtering, lift-off, and other processes to obtain the logic/analog transistor.

Then, an interlayer isolation layer may be formed on the front-end circuit by using a process such as plasma chemical vapor deposition to achieve electrical insulation in a non-contact region between the back-end metal interconnect layer and the front-end circuit. The interlayer isolation layer may be made of silicon dioxide to be compatible with a very-large-scale integrated circuit process while reducing the difficulty and costs of manufacturing the interlayer isolation layer on the front-end circuit. The interlayer isolation layer may have a thickness ranging from 100 nm to 400 nm. Certainly, the material and the thickness of the interlayer isolation layer may alternatively be other materials and thicknesses that meet working requirements.

As shown in FIG. 3 to FIG. 5, finally, the back-end metal interconnect layer 14 and the back-end power gating circuit 15 are manufactured on the interlayer isolation layer 13 by using a back-end-of-line (BEOL) process. Specifically, for a process of manufacturing a power gating transistor 151 of the back-end power gating circuit 15, reference may be made to the process of manufacturing the logic/analog transistor 121 described above. Details are not described herein again.

As described above, when the back-end power gating circuit includes at least one power gating transistor, a channel of the at least one power gating transistor includes may be formed by amorphous indium gallium zinc oxide. In this case, it is advantageous to use a low temperature process to form the back-end metal interconnect layer and the back-end power gating circuit above the front-end circuit to prevent the front-end circuit from being damaged by a high temperature process. Specifically, a processing temperature of the low temperature process may be greater than 0 and less than or equal to 350° C.

Compared with the prior art, the beneficial effects of the manufacturing method of a 3D integrated circuit provided in the embodiments of the present disclosure are the same as the beneficial effects of the 3D integrated circuit provided in the embodiments of the present disclosure. Details are not described herein again.

It should be noted that, the front-end circuit and the back-end metal interconnect layer may be formed in a plurality of manners. How to form the foregoing structure is not the main feature of the present disclosure, and therefore, in this specification, is only briefly described, such that those of ordinary skill in the art can easily implement the present disclosure. Those of ordinary skill in the art can completely figure out other manners to make the foregoing structure.

In the above description, the technical details such as the composition and etching of each layer are not described in detail. However, those skilled in the art should understand that layers and regions with desired shapes can be formed by various technical means. In addition, in order to form the same structure, those skilled in the art can also design a method that is not completely the same as the method described above. In addition, although the various embodiments are described above separately, this does not mean that the measures in the various embodiments cannot be used in combination.

The embodiments of the present disclosure are described above. However, these embodiments are for illustrative purposes only, and are not intended to limit the scope of the present disclosure. The scope of the present disclosure is defined by the appended claims and their equivalents. Those skilled in the art can make various substitutions and modifications to the present disclosure without departing from the scope of the present disclosure, but such substitutions and modifications should all fall within the scope of the present disclosure.

1. A three-dimensional integrated circuit, comprising: a substrate, a front-end circuit formed on the substrate, a back-end metal interconnect layer, and a back-end power gating circuit, wherein the back-end metal interconnect layer is formed on the front-end circuit, the back-end power gating circuit is located in the back-end metal interconnect layer, and the front-end circuit is electrically connected to a power supply or a ground wire through the back-end metal interconnect layer and the back-end power gating circuit.

2. The three-dimensional integrated circuit according to claim 1, wherein the front-end circuit and the back-end power gating circuit are vertically stacked along a thickness direction of the substrate.

3. The three-dimensional integrated circuit according to claim 1, wherein the back-end power gating circuit comprises at least one power gating transistor; and
the at least one power gating transistor comprises a channel made of amorphous indium gallium zinc oxide.

4. The three-dimensional integrated circuit according to claim 1, wherein the three-dimensional integrated circuit further comprises an interlayer isolation layer located between the front-end circuit and the back-end metal interconnect layer; and
the interlayer isolation layer is made of silicon dioxide, and/or the interlayer isolation layer has a thickness ranging from 100 nm to 400 nm.

5. The three-dimensional integrated circuit according to claim 1, wherein the front-end circuit comprises at least one logic/analog transistor; and
the at least one logic/analog transistor comprises a source and a drain that are made of titanium and/or gold, and/or a gate made of molybdenum; and/or a gate dielectric layer of the at least one logic/analog transistor is formed by stacking a first aluminum oxide layer and a first silicon dioxide layer, and the first silicon dioxide layer is located between a channel of the logic/analog transistor and the first aluminum oxide layer.

6. The three-dimensional integrated circuit according to claim 1, wherein the back-end power gating circuit comprises at least one power gating transistor; and
the at least one power gating transistor comprises a source and a drain that are made of titanium and/or gold, and/or a gate made of titanium and/or gold; and/or a gate dielectric layer of the at least one power gating transistor is formed by stacking a second aluminum oxide layer and a second silicon dioxide layer, and the second silicon dioxide layer is located between a channel of the power gating transistor and the second aluminum oxide layer.

7. A manufacturing method of a three-dimensional integrated circuit, comprising:
providing a substrate;
forming a front-end circuit on the substrate; and
forming, on the front-end circuit, a back-end metal interconnect layer and a back-end power gating circuit located in the back-end metal interconnect layer, wherein the front-end circuit is electrically connected to a power supply or a ground wire through the back-end metal interconnect layer and the back-end power gating circuit.

8. The manufacturing method of a three-dimensional integrated circuit according to claim 7, wherein after the forming a front-end circuit on the substrate, and before the forming, on the front-end circuit, a back-end metal interconnect layer and a back-end power gating circuit located in the back-end metal interconnect layer, the manufacturing method of a three-dimensional integrated circuit further comprises:
forming an interlayer isolation layer on the front-end circuit, wherein the interlayer isolation layer is made of silicon dioxide, and/or the interlayer isolation layer has a thickness ranging from 100 nm to 400 nm.

9. The manufacturing method of a three-dimensional integrated circuit according to claim 7, wherein the back-end power gating circuit comprises at least one power gating transistor, and the at least one power gating transistor comprises a channel formed by amorphous indium gallium zinc oxide.

10. The manufacturing method of a three-dimensional integrated circuit according to claim 7, wherein the back-end metal interconnect layer and the back-end power gating circuit are formed by a low temperature process at a processing temperature of greater than 0 and less than or equal to 350° C.
